(19) United States
(12) Patent Application Publication
(10) Pub. No.: US 2023/0366484 A1
(43) Pub. Date: Nov. 16, 2023

(54) HEAT-TRANSFERRING VALVE FLEXURE AND METHODS

(71) Applicant: LAM RESEARCH CORPORATION, Fremont, CA (US)

(72) Inventor: Karl Frederick Leeser, West Linn, OR (US)

(21) Appl. No.: 18/026,322

(22) PCT Filed: Aug. 30, 2021
(86) PCT No.: PCT/US2021/048259

§ 371 Date: Mar. 14, 2023

Related U.S. Application Data
(60) Provisional application No. 63/078,705, filed on Sep. 15, 2020.

(51) Int. Cl. F16K 49/00; C23C 16/455; F16K 7/17

(52) U.S. Cl. CPC F16K 49/007; C23C 16/45544; F16K 7/17

(57) ABSTRACT

In some examples, a valve flexure for a flow control valve is provided. An example valve flexure comprises a first diaphragm; a second diaphragm, the second diaphragm directly or indirectly connected to the first diaphragm about a peripheral portion of the valve flexure, the connected first and second diaphragms enclosing an inner volume of the valve flexure; and a heat transfer medium disposed within the inner volume of the valve flexure.

### CLAIM OF PRIORITY

This application claims the benefit of priority to U.S. Patent Application Ser. No. 63/078,705, filed on Sep. 15, 2020, which is incorporated by reference herein in its entirety.

### FIELD

The present disclosure relates to substrate processing systems, and more particularly to a valve flexure for a vapor control valve in a substrate processing system.

### BACKGROUND

Substrate processing systems may be used to deposit a film on substrates such as semiconductor wafers. Example processes that may be performed on a substrate include, but are not limited to, chemical vapor deposition (CVD), atomic layer deposition (ALD), plasma-enhanced CVD (PECVD), and plasma-enhanced ALD (PEALD). A substrate may be arranged on a substrate support, such as a pedestal, an electrostatic chuck (ESC), etc., in a processing chamber of the substrate processing system. During processing, a gas mixture is introduced into the processing chamber and plasma may be used to enhance chemical reactions within the processing chamber.

Ultra-high purity (UHP) valves exist in the semiconductor industry for handling gases and vapors with close to pristine defect performance and low metal contamination. These valves typically include some form of mechanical flexure or diaphragm that moves to open or close the valve. A flexure typically flexes against a metallic or polymer sealing surface surrounding an aperture. The use of such valves in controlling gas flow is generally understood, but in vapor flow control applications the use of such valves is significantly more complicated.

For example, in such applications, condensation is a major concern. Conventional attempts to address this have included providing a vapor flow control valve and its associated supply and discharge lines with significant heat to prevent condensation of vapors on cold surfaces and the production of undesirable particles. The effective heating of a valve diaphragm can be rendered even more challenging in that the typical vapor that flows through a UHP valve is of high molecular weight. As the vapor flows through and out of the restricted orifice of a valve seal-flexure gap, it experiences a significant adiabatic expansion, which strongly cools the surfaces of surrounding components. The relatively high thermal mass of the surrounding components experiences negligible temperature drop due to this cooling phenomenon, but the valve diaphragm—which is extremely thin—is of much lower thermal mass and can experience significant cooling and potential performance impairment.

In modern semiconductor manufacturing, vapor flows are ever-increasing to enable faster deposition rates. Newer processes of interest, such as atomic layer deposition (ALD), result in even faster valve opening times, which exacerbate the flexure cooling phenomenon. Heat transfer from the valve body across the diaphragm has a fixed time constant, and as manufacturing processes become faster, it becomes very difficult if not impossible to supply sufficient heat to the thermally isolated diaphragm to prevent it from malfunctioning.

The background description provided here is to generally present the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

In some examples, a valve flexure for a flow control valve is provided. An example valve flexure comprises a first diaphragm; a second diaphragm, the second diaphragm directly or indirectly connected to the first diaphragm about a peripheral portion of the valve flexure, the connected first and second diaphragms enclosing an inner volume of the valve flexure; and a heat transfer medium disposed within the inner volume of the valve flexure.

In some examples, a configuration of the first and second diaphragms and the heat transfer medium is selected to provide a specified dynamic response for the valve flexure or the valve.

In some examples, a configuration of the first and second diaphragms and the heat transfer medium is selected to provide a specified heat transfer characteristic of the valve flexure.

In some examples, a valve opening or valve closing movement of the first diaphragm induces a simultaneous or corresponding valve opening or valve closing movement of the second diaphragm.

In some examples, the heat transfer medium is incompressible.

In some examples, the valve flexure is devoid of a side wall.

In some examples, the first diaphragm is connected to the second diaphragm by a side wall. In some examples, the side wall defines a cylindrical side wall extending around the circumference of the valve flexure. In some examples, the side wall includes bellows.

In some examples, the valve flexure includes an asymmetry with respect to the first and second diaphragms. In some examples, a degree of asymmetry is selected to provide a specified dynamic response of the flexure.

In some examples, the first diaphragm or the second diaphragm includes one or more of the following materials: SPRN 510, SPRN 100, and ELGILOY.

In some examples, the heat transfer medium has a dynamic viscosity of 1e-4 to 2e-2 Pa-s. In some examples, the heat transfer medium has a thermal conductivity of 0.1 to 0.7 W/m° K. In some examples, the heat transfer medium includes an alcohol.

In some examples, the heat transfer medium includes a dual-phase medium. In some examples, the dual-phase medium moves or cycles between compressible and incompressible forms based on a valve flow control characteristic, valve status, or an operating condition.

In some examples, a flow control valve comprises a valve flexure, the valve flexure including any one or more of the valve flexure elements summarized above.

In some examples, a flow control valve comprises an inlet to admit a gas or vapor into the valve; an outlet to discharge the gas or vapor from the valve; a valve flexure to open or close the valve, the valve flexure movable to seat on and unseat from a valve seal located between the inlet and outlet of the valve; a periphery of the valve flexure connected to one or more valve components, the connection defining or partitioning out an atmospheric side of the flow control valve; and an interstitial liquid located above the valve flexure, the interstitial liquid occupying, on the atmospheric side of the valve, at least some interstitial spaces adjacent or between the one or more valve components of the valve.

In some examples, the flow control valve further comprises an interstitial fluid column or reservoir. In some examples, the interstitial liquid is filled to a depth in the range of 1-30 mm above the valve flexure, or within the valve. In some examples, the interstitial liquid has a dynamic viscosity of 1e-4 to 2e-2 Pa-s. In some examples, the interstitial liquid has a thermal conductivity of 0.1 to 0.7 W/m° K. In some examples, the interstitial liquid includes an alcohol. IN some examples, the interstitial liquid includes a dual-phase medium.

In some examples, a substrate processing system comprises a processing chamber; a gas or vapor distribution device; and a flow control valve connected to the gas or vapor distribution device, the flow control valve including a valve flexure, the valve flexure including any one or more of the valve flexure elements summarized above. In some examples, the flow control valve further comprises any one or more of the flow control valve elements summarized above.

In some examples, a substrate processing system comprises a processing chamber; a gas or vapor distribution device; and a flow control valve connected to the gas or vapor distribution device, the flow control valve including any one or more of the flow control valve elements summarized above.

Further areas of applicability of the present disclosure will become apparent from the detailed description, the claims, and the drawings. The detailed description and specific examples are intended for purposes of illustration only and are not intended to limit the scope of the disclosure.

### DESCRIPTION OF THE DRAWINGS

Some embodiments are illustrated by way of example and not limitation in the views of the accompanying drawings:

FIG. 1 is a functional block diagram of an example of a substrate processing system for annealing an example film according to the present disclosure.

FIG. 2 is a sectional side view of a valve in which examples of the disclosure may be deployed, according to example embodiments.

FIG. 3 is an enlarged sectional side view of a portion of FIG. 2, illustrating a deployed example of the disclosure.

FIG. 4 is an enlarged sectional side view of a portion of FIG. 2, illustrating another deployed example of the disclosure.

FIG. 5 is a flow chart including example operations in a method, according to an example embodiment.

FIG. 6 is a block diagram illustrating an example of a system controller upon which one or more example embodiments may be implemented, or by which one or more example embodiments may be controlled.

### DESCRIPTION

The description that follows includes systems, methods, techniques, instruction sequences, and computing machine program products that embody illustrative embodiments of the present inventive subject matter. In the following description, for purposes of explanation, numerous specific details are outlined to provide a thorough understanding of example embodiments. It will be evident, however, to one skilled in the art, that the present embodiments may be practiced without these specific details.

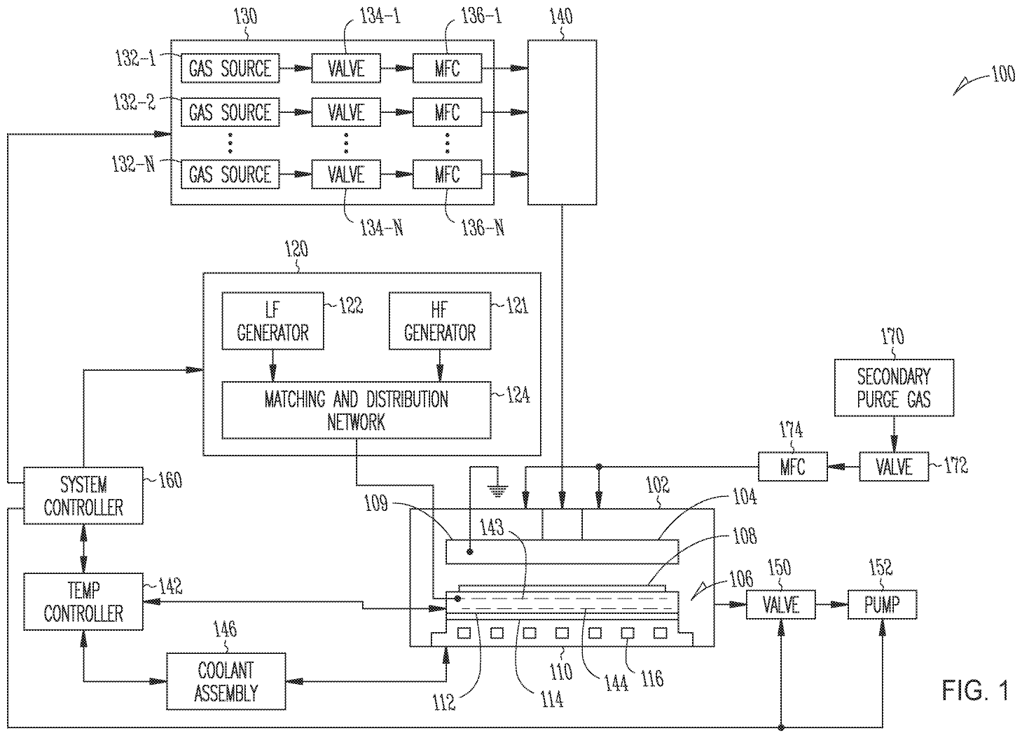

Referring now to FIG. 1, an example substrate processing system 100 for performing deposition is shown. Examples of the present disclosure may be utilized in the processing system 100. While a PECVD substrate processing system is shown, a PEALD substrate processing system or other substrate processing system may be used. The substrate processing system 100 includes a processing chamber 102 that encloses other components of the substrate processing chamber 102 and contains plasma. The substrate processing chamber 102 includes a gas distribution device 104 and substrate support 106, such as an electrostatic chuck (ESC). During operation, substrate 108 is arranged on the substrate support 106.

In some examples, the gas distribution device 104 may include a powered showerhead 109 that distributes process gases over the substrate 108 and induces ion bombardment. The showerhead 109 may include a stem portion including one end connected to a top surface of the processing chamber 102. A base portion is generally cylindrical and extends radially outwardly from an opposite end of the stem portion at a location that is spaced from the top surface of the processing chamber 102. A substrate-facing surface or faceplate of the base portion of the showerhead 109 includes a plurality of distributed holes through which process gas flows. The gas distribution device 104 may be made of a metallic material and may act as an upper electrode. Alternately, the gas distribution device 104 may be made of a non-metallic material and may include an embedded electrode. In other examples, the upper electrode may include a conducting plate and the process gases may be introduced in another manner. The substrate support 106 includes a conductive base plate 110 that acts as a lower electrode. The baseplate 110 supports a heating plate 112, which may correspond to a ceramic multi-zone heating plate. A thermal resistance layer 114 may be arranged between heating plate 112 and the base plate 110. Baseplate 110 may include one or more coolant channels 116 for flowing coolant through baseplate 110.

An RF generating system 120 generates and outputs an RF voltage to one of the upper electrodes (e.g., the gas distribution device 104) and the lower electrode (e.g., baseplate 110 of the substrate support 106). The other one of the upper electrode and the lower electrode may be DC grounded, AC grounded or floating. In some examples, the RF generating system 120 may supply dual-frequency power including a high-frequency (HF) generator 121 and a low-frequency (LF) generator 122 that generate the HF and LF power (at predetermined frequencies and power levels, respectively) that is fed by a matching and distribution network 124 to the upper electrode or the lower electrode (or the showerhead 109).

A gas delivery system 130 includes one or more gas sources 132-1, 132-2, . . . , and 132-N (collectively, gas sources 132), where N is an integer greater than zero. The gas sources 132 supply one or more process gas mixtures, dopants, carrier gas, annealing gasses, and/or purge gas. The annealing gasses may include H₂ and/or O₂, or a mixture thereof. In some examples, the gas delivery system 130 delivers a mixture of TEOS gas, a gas including an oxygen species and argon (Ar) gas during deposition, and dopants including triethyl phosphate (TEPO) and/or triethyl borate (TEB). In some examples, diffusion of the dopants occurs from the gas phase. For example, a carrier gas (e.g., nitrogen, argon, or other) is enriched with the desired dopant (also in gaseous form, e.g., triethyl phosphate (TEPO) and/or triethyl borate (TEB)) and led to the silicon wafer on which a concentration balance can take place. In subsequent processes, a wafer may be placed in a quartz tube that is heated to a certain temperature.

In other examples, diffusion of the dopants occurs using a liquid source. As dopant liquid sources, triethyl phosphate (TEPO) and/or triethyl borate (TEB) can be used. A carrier gas is led through these liquids and transports the desired dopant in a gaseous state. If the entire wafer is not required to be doped, certain areas can be masked with silicon dioxide. The dopants do not penetrate through the oxide, and therefore no doping takes place at these locations. To avoid tensions or even fractions of the wafer, a quartz tube containing one or more wafers is gradually heated (e.g., +10° C. per minute) to 900° C. Subsequently, the dopant is led to the wafers inside the quartz tube. To set the diffusion process in motion, the temperature is then increased up to 1200° C.

Returning to FIG. 1, the gas sources 132 are connected by valves 134-1, 134-2, . . . , and 134-N (collectively, valves 134) and mass flow controllers 136-1, 136-2, . . . , and 136-N (collectively, mass flow controllers 136) to a mixing manifold 140. The gases are supplied to the mixing manifold 140 and mixed therein. An output of the mixing manifold 140 is fed to processing chamber 102. In some examples, the output of the mixing manifold 140 is fed to the showerhead 109. In some examples, an annealing gas is fed to processing chamber 102 for in-situ annealing. Secondary purge gas 170 may be supplied to processing chamber 102 such as behind the showerhead 109 via a valve 172 and MFC 174. In some examples, valves 134 include vapor flow control valves.

A temperature controller 142 may be connected to a plurality of thermal control elements (TCEs) 143 and 144 arranged in the heating plate 112. For example, the TCEs 143 and 144 may include, but are not limited to, respective macro TCEs corresponding to each zone in a multi-zone heating plate and/or an array of micro TCEs disposed across multiple zones of a multi-zone heating plate. The temperature controller 142 may be used to control the plurality of TCEs 143 and 144 to control the temperature of the substrate support 106 and the substrate 108. The temperature controller 142 may communicate with a coolant assembly 146 to control coolant flow through the channels 116. For example, the coolant assembly 146 may include a coolant pump and reservoir. The temperature controller 142 operates the coolant assembly 146 to selectively flow the coolant through the channels 116 to cool the substrate support 106. A valve 150 and pump 152 may be used to control pressure and to evacuate reactants from the processing chamber 102. A system controller 160 may be used to control components of the substrate processing system 100. Although shown as separate controllers, the temperature controller 142 may be implemented within the system controller 160.

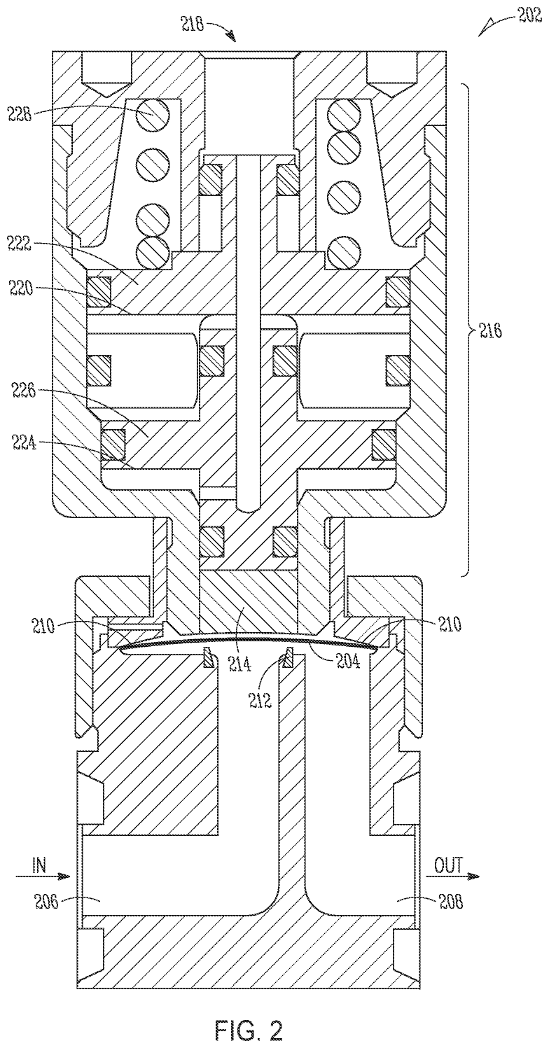

FIG. 2 is a sectional view of an example UHP valve 202 in which examples of the present disclosure may be employed. The valve 202 operates to control a flow of vapor from a vapor flow inlet 206 to a vapor flow outlet 208. The UHP valve 202 includes a diaphragm, or flexure 204. The flexure 204 is a flexible, thin body in thermal communication with the valve 202 only about its circumference 210. The flexure 204 can flex down or up in the view to be seated on or unseated from an annular seal 212. The unseating or seating of the flexure 204 opens or closes the UHP valve 202 to permit or deny passage of vapor from the inlet 206 to outlet 208. Interim flexure 204 positions, corresponding for example to a degree of opening or closing of valve 202, regulates the flow of the vapor.

In some examples, the movement of the flexure 204 is controlled by a plunger component 214. The plunger component 214 is connected via various means to a spring-loaded assembly shown generally at 216. The spring-loaded assembly 216 includes a spring 228. The spring-loaded assembly 216 provides a continuous downward seating force which seats the flexure 204 when the valve 202 is not actuated. In this configuration words, valve 202 may be said to be “default-closed”. To permit the flow of vapor, valve 202 is actuated.

The valve 202 is actuated via the introduction of pressurized control gas into an upper port 218. When actuated, the control gas pressure bears against a series of upwardly movable components, described below, located inside the valve. The pressure of the gas acting on surfaces of these components overcomes the downward seating force generated by the spring-loaded assembly 216 and enables the valve 202 to open. In some example arrangements of the upwardly movable components, the gas pressure acts on lower faces 220 and 224 of respective actuators 222 and 226 to move the actuators 222, 226 upwardly under gas pressure. Upward movement of the actuators 222 and 226 causes the connected plunger component 214 to move upwardly and allow the flexure 204 to unseat from the seal 212 and open valve 202.

As mentioned above, in vapor flow control applications, avoiding the potential condensation of the vapor can present significant challenges. For example, a vapor flow control valve and its associated supply and control lines may require significant heat to prevent condensation of the vapor on cold surfaces and the production of undesirable particles. Effective heating of a valve diaphragm is inherently challenging because a typical vapor flowing through the valve usually has a high molecular weight. As the vapor flows past the restricted opening of the valve seat and flexure gap, the vapor typically experiences an adiabatic expansion and cools surrounding surfaces. The relatively high thermal mass of a valve body may experience negligible temperature drop due to this phenomenon, but the valve diaphragm, which is usually extremely thin, is of much lower thermal mass accordingly and will experience significant cooling.

In other aspects, in current semiconductor manufacturing applications, vapor flows are continuously being increased to enable faster deposition rates. Newer processes of interest such as atomic layer deposition (ALD) result in even faster valve opening times, which can exacerbate the flexure cooling phenomenon described above. Heat transfer from the valve body across the diaphragm has a fixed time constant, and as manufacturing processes become faster, it becomes very difficult if not impossible to supply sufficient heat to the interior of a diaphragm located far away from a valve body. The thermally isolated valve diaphragm becomes prone to malfunction.

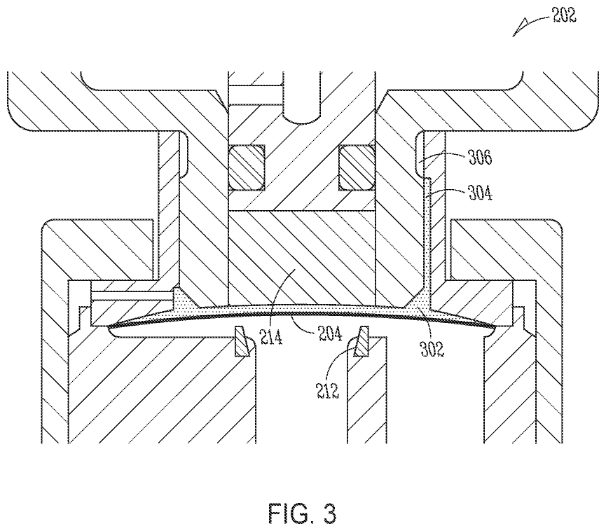

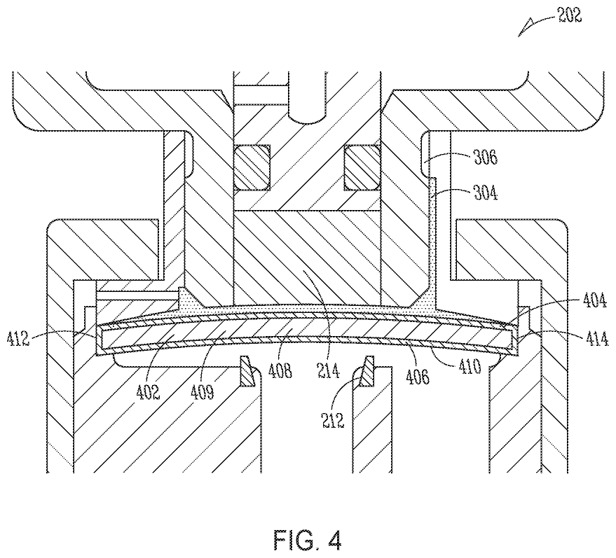

In this regard, reference is now made to FIGS. 3-4 of the accompanying drawings. FIG. 3 includes an enlarged section view of a portion of valve 202 of FIG. 2. As above, the illustrated valve 202 includes a flexible flexure (or diaphragm) 204 that can move or flex to seat onto or be unseated from, a valve seal 212. As before, flexure 204 interacts with a plunger component 214 to open or close valve 202. In a first aspect of the disclosure, an interstitial liquid 302 fills, or at least partially fills, existing cavities or interstitial spaces located above and between components surrounding the flexure 204, as shown. The interstitial liquid 302 acts as a thermal connection between the flexure 204 and surrounding components of valve 202 and seeks to mitigate the thermal isolation problems discussed above.

Generally speaking, the interstitial liquid 302 provides good heat transfer characteristics while allowing the flexure 204 to move in an unrestricted manner. In other words, the dynamic response of the flexure 204 (often particularly important in a UPC valve, for example) is substantially preserved notwithstanding the presence of the interstitial liquid 302. In some examples, the interstitial liquid 302 is filled to a depth, in increments of a millimeter (mm), in a range of 1-30 mm above the flexure 204, or within the valve 202. In some examples, the interstitial liquid 302 has a dynamic viscosity of 1e-4 to 2e-2 Pa-s and a thermal conductivity of 0.1 to 0.7 W/m° K. In some examples, the interstitial liquid 302 includes an alcohol.

In some examples, an interstitial fluid column or reservoir is provided as shown at 304. In some examples, reservoir 304 includes a small, evacuated volume 306 at its upper end. The interstitial liquid 302 may be introduced into reservoir 304 by a syringe, or in another manner. In some examples, one or more of the components surrounding the flexure 204 includes one or more formations serving as a dam or restriction to retain the interstitial liquid 302 in place as the flexure 204 moves up and down in operation of the valve 202.

In some examples, the interstitial liquid 302 is incompressible. In some examples, the interstitial liquid 302 is provided not merely as a “liquid” per se but as a fluid, or in dual-phase form. In some examples, fluid 302 may move from an incompressible liquid phase to a compressible gaseous phase or vice versa. A phase change may occur in certain operations of valve 202, or under certain operating conditions. In some examples, fluid 302 continuously cycles between these two phases in certain operations of valve 202, or under certain conditions.

FIG. 4 includes an enlarged section view of a portion of valve 202 of FIG. 2. In a second aspect of the disclosure, the illustrated valve 202 includes in this instance a “dual” or “pillow” type of flexible flexure or diaphragm 402 (hereinafter referred to as a dual flexure 402) that can seat onto, or unseat from, a valve seal 212. For purposes of explanation, the dual flexure 402 is shown in a somewhat enlarged or simplified view as compared to a configuration that might be provided in real life. As above in the discussion of flexure 204, the dual flexure 402 interacts with a plunger component 214 to open or close the valve 202. The dual flexure 402 may be of uniform construction or composite or hollow form. The dual flexure 402 may include an internal volume as described more fully below.

In some examples, the dual flexure 402 includes a composite structure comprising of pair of opposed diaphragms 404 and 406 that sandwich or contain between them a liquid heat transfer medium 408. Some examples of a dual flexure 402 may generally include the first diaphragm; a second diaphragm, the second diaphragm connected to the first diaphragm about a periphery of the flexure, the connected first and second diaphragms enclosing an inner volume of the flexure; and a heat transfer medium located within the inner volume.

In some examples, the liquid heat transfer medium 408 provides good heat transfer characteristics while allowing the dual flexure 402 to move in an unrestricted manner.

In some examples, the liquid heat transfer medium 408 does not inhibit the dynamic response of the dual flexure 402 yet enables heat to spread more rapidly to reach generally all regions of the dual flexure 402 and mitigate at least some of the thermal isolation problems discussed above. In some examples, the dynamic response (i.e. an ability to open and close a valve, at speed) of the dual flexure 402 as compared to a conventional flexure 204 is substantially the same. In some examples, a valve opening or closing movement of an upper diaphragm 404 is replicated by, or induces, a simultaneous or corresponding movement of a lower diaphragm 406 of the dual flexure 402. In some examples, the heat transfer medium 408 is incompressible, and in some examples, this incompressibility entrains or induces by vacuum, the corresponding movement of one diaphragm of the dual flexure 402 when another diaphragm of the dual flexure 402 moves.

Some examples of the flexure 402 include a flexible pillow-shaped cylindrical sack or enclosure 410, for example as shown in FIG. 4. The enclosure 410 includes or defines an internal volume 409. Upper and lower walls or layers of enclosure 410 may include the upper and lower diaphragms 404 and 406. The layers may be internal or external layers of the dual flexure 402. The enclosure 410 may, or may not, include side walls 412 and 414. In some examples, the side walls 412 and 414 form part of the same wall, for example, a single cylindrical side wall extending around the circumference of the flexure 402. Portions of the flexure 402 may include a bellows. For example, a bellows structure may be included in a side wall 412 or 414 of the flexure 402 or an upper or lower wall thereof. In some examples, flexure 402 includes internal layers. The internal layers may, or may not, enclose or interact with the heat transfer medium 408. In some examples, the flexure 402 includes a squat, cylindrical shell to enclose the heat transfer medium 408. In some examples, flexure 402 includes a mechanical enclosure 410 which includes a compressible or incompressible element to transfer heat from valve 202 to flexure 402. Some examples of a dual flexure 402 include an asymmetry between opposed diaphragms 404 and 406, or between the side walls 412 and 414. A degree of asymmetry may be selected to provide a desired dynamic response of the flexure 402, for example, to make the valve 202 open faster than it closes, or vice versa, for vapor control purposes.

In some examples, the flexure 402, or the enclosure 410, is pre-filled with a heat transfer medium 408. In some instances, the flexure 402 or enclosure 410 is injectable with a heat transfer medium 408. The flexure 402 or enclosure 410 may include a flexible material such as SPRN 510, SPRN 100, or ELGILOY. The upper and lower walls of the flexures, for example, the diaphragms 404 and 406, or one or more side walls of the enclosure 410, maybe composed entirely or partly of such material.

Generally speaking, the heat transfer medium 408 is selected to provide good heat transfer characteristics while allowing the flexure 402 to move in an unrestricted manner. In some examples, the interstitial liquid 302 and the heat transfer medium 408 are the same. In some examples, the heat transfer medium 408 has a dynamic viscosity of 1e-4 to 2e-2 Pa-s and a thermal conductivity of 0.1 to 0.7 W/m° K. An example of a suitable heat transfer medium 408 is Dynalene HC-10, a non-toxic, non-flammable, potassium formate product produced by Dynalene, Inc. of Whitehall, PA with the following properties:

| Temperature | Dynamic Viscosity | Thermal Conductivity |
|---|---|---|
| (° C.) | (Pa-s) | (W/m° K) |
| 20 | 1.79E−03 | 5.24E−01 |
| 100 | 6.63E−04 | 6.04E−01 |
| 150 | 4.31E−04 | 6.54E−01 |

In some examples, the heat transfer medium 408 is provided as a low-viscosity fluid, a low-viscosity thin gel, or in dual-phase form. In other words, the flexure 402 or enclosure 410 may not always be incompressible in operation. In some examples, a heat transfer medium 408 moves from an incompressible liquid form to a compressible gaseous form, or vice versa, under certain operations or conditions of valve 202. In some examples, the heat transfer medium 408 cycles between these two phases in certain operations of the valve 202, or under certain conditions. The change in form of the heat transfer medium 408 may be based on a desired vapor flow control characteristic, the status of the valve, or an operating condition.

The first (interstitial liquid) and second (enhanced diaphragm) aspects of the disclosure may be deployed independently, or in conjunction with one another to address the problems discussed herein. A conventional thin diaphragm has little thermal mass to store heat and replenish any heat lost. Moreover, the thin diaphragm structure has poor heat conduction from the valve body and is slow to replenish heat from there. In addressing these problems, both aspects of this disclosure seek to include a high-density, low-viscosity liquid on the atmospheric (non-vapor) side of the diaphragm to increase both the effective thermal mass of the diaphragm as well as its ability to collect heat from the valve body and associated components. In liquid form, an interstitial liquid or heat transfer medium is inherently flexible and thus has a minimal restriction on the range of movement of a diaphragm. Additionally, the provision of an appropriately low viscosity mitigates negative impacts of the liquid or medium on valve actuation speeds.

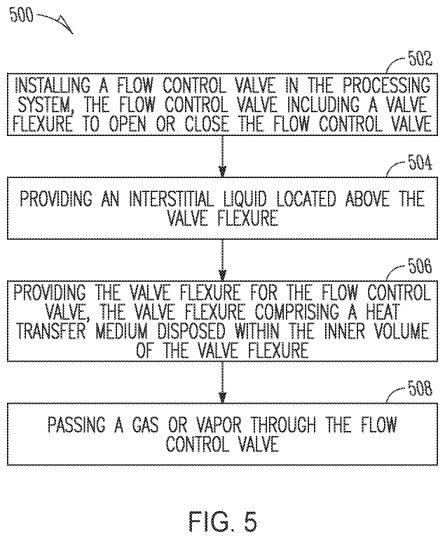

Some of the embodiments disclosed herein include methods. With reference to FIG. 5, operations in a method 500 of implementing a substrate processing system includes, at operation 502, installing a flow control valve in the processing system, the flow control valve including an inlet to admit a gas or vapor into the flow control valve; an outlet to discharge the gas or vapor from the flow control valve; a valve flexure to open or close the flow control valve, the valve flexure movable to seat on and unseat from a valve seal located between the inlet and outlet of the flow control valve: and a periphery of the valve flexure connected to one or more valve components, the connection defining or partitioning out an atmospheric side of the flow control valve; the method 500 further comprising, at operation 504, providing an interstitial liquid located above the valve flexure, the interstitial liquid occupying, on the atmospheric side of the valve, at least some interstitial spaces adjacent or between the one or more valve components of the valve.

In some examples, the method 500 further comprises, at operation 506, providing the valve flexure for the flow control valve, the valve flexure comprising: a first diaphragm: a second diaphragm, the second diaphragm directly or indirectly connected to the first diaphragm about a peripheral portion of the valve flexure, the connected first and second diaphragms enclosing an inner volume of the valve flexure; and a heat transfer medium disposed within the inner volume of the valve flexure.

In some examples, method 500 further comprises, at operation 508, passing gas or vapor through the flow control valve.

In some examples, a method of implementing a substrate processing system includes installing a flow control valve in the processing system, the flow control valve including a first diaphragm; a second diaphragm, the second diaphragm directly or indirectly connected to the first diaphragm about a peripheral portion of a valve flexure, the connected first and second diaphragms enclosing an inner volume of the valve flexure; and a heat transfer medium disposed within the inner volume of the valve flexure.

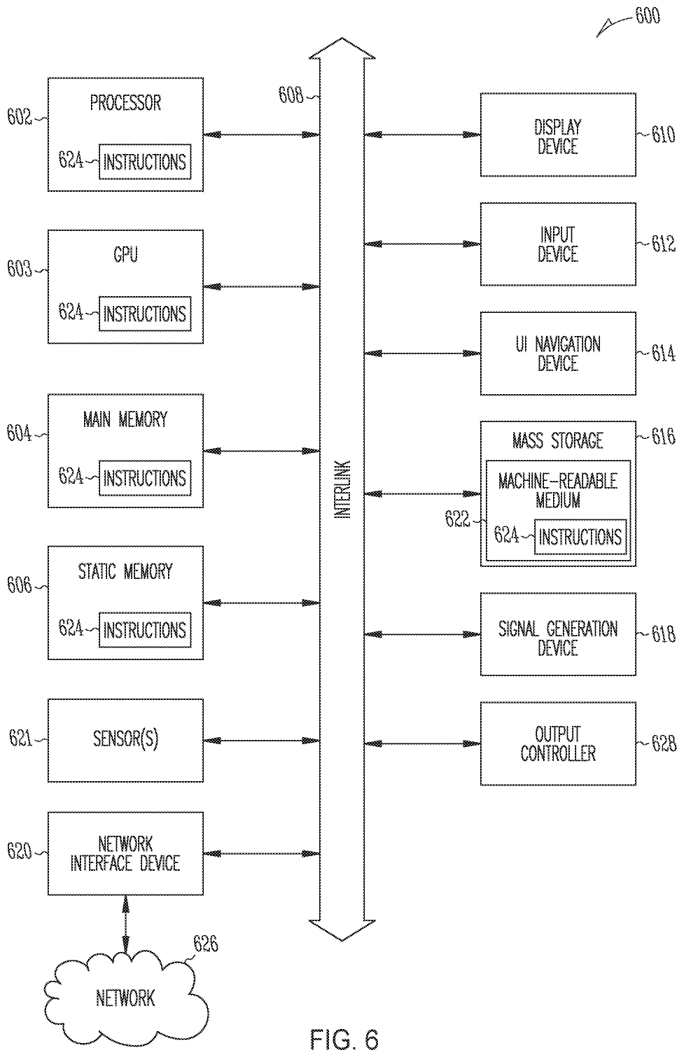

FIG. 6 is a block diagram illustrating an example of a machine, such as a system controller 160 of FIG. 1, by which one or more example process embodiments described herein may be controlled. In alternative embodiments, the system controller 600 may operate as a standalone device or may be connected (e.g., networked) to other machines. In a networked deployment, the system controller 600 may operate in the capacity of a server machine, a client machine, or both in server-client network environments. In an example, the system controller 600 may act as a peer machine in a peer-to-peer (P2P) (or other distributed) network environment. Further, while only a single machine (i.e., the system controller 600) is illustrated, the term “machine” shall also be taken to include any collection of machines that individually or jointly execute a set (or multiple sets) of instructions to perform any one or more of the methodologies discussed herein, such as via cloud computing, software as a service (SaaS), or other computer cluster configurations.

Examples, as described herein, may include, or may operate by, logic, a number of components or mechanisms. The circuitry is a collection of circuits implemented in tangible entities that include hardware (e.g., simple circuits, gates, logic, etc.). Circuitry membership may be flexible over time and underlying hardware variability. Circuitries include members that may, alone or in combination, perform specified operations when operating. In an example, the hardware of the circuitry may be immutably designed to carry out a specific operation (e.g., hardwired). In an example, the hardware of the circuitry may include variably connected physical components (e.g., execution units, transistors, simple circuits, etc.) including a computer-readable medium physically modified (e.g., magnetically, electrically, by the moveable placement of invariant massed particles, etc.) to encode instructions of the specific operation. In connecting the physical components, the underlying electrical properties of a hardware constituent are changed (for example, from an insulator to a conductor or vice versa). The instructions enable embedded hardware (e.g., the execution units or a loading mechanism) to create members of the circuitry in hardware via the variable connections to carry out portions of the specific operation when in operation. Accordingly, the computer-readable medium is communicatively coupled to the other components of the circuitry when the device is operating. In an example, any of the physical components may be used in more than one member of more than one circuitry. For example, under operation, execution units may be used in the first circuit of a first circuitry at one point in time and reused by a second circuit in the first circuitry, or by a third circuit in a second circuitry, at a different time.

The system controller (e.g., computer system) 600 may include a hardware processor 602 (e.g., a central processing unit (CPU), a hardware processor core, or any combination thereof), a graphics processing unit (GPU) 603, a main memory 604, and a static memory 606, some or all of which may communicate with each other via an interlink (e.g., bus) 608. The system controller 600 may further include a display device 610, an alphanumeric input device 612 (e.g., a keyboard), and a user interface (UI) navigation device 614 (e.g., a mouse). In an example, the display device 610, alphanumeric input device 612, and UI navigation device 614 may be a touch screen display. The system controller 600 may additionally include a mass storage device (e.g., drive unit) 616, a signal generation device 618 (e.g., a speaker), a network interface device 620, and one or more sensors 621, such as a Global Positioning System (GPS) sensor, compass, accelerometer, or another sensor. The system controller 600 may include an output controller 628, such as a serial (e.g., universal serial bus (USB)), parallel, or other wired or wireless (e.g., infrared (IR), near field communication (NFC), etc.) connection to communicate with or control one or more peripheral devices (e.g., a printer, card reader, etc.).

The mass storage device 616 may include a machine-readable medium 622 on which is stored one or more sets of data structures or instructions 624 (e.g., software) embodying or utilized by any one or more of the techniques or functions described herein. The instructions 624 may also reside, completely or at least partially, within the main memory 604, within the static memory 606, within the hardware processor 602, or within the GPU 603 during execution thereof by the system controller 600. In an example, one or any combination of the hardware processor 602, the GPU 603, the main memory 604, the static memory 606, or the mass storage device 616 may constitute machine-readable media 622.

While the machine-readable medium 622 is illustrated as a single medium, the term “machine-readable medium” may include a single medium or multiple media (e.g., a centralized or distributed database, and/or associated caches and servers) configured to store the one or more instructions 624.

The term “machine-readable medium” may include any medium that can store, encode, or carry instructions 624 for execution by the system controller 600 and that cause the system controller 600 to perform any one or more of the techniques of the present disclosure, or that can store, encode, or carry data structures used by or associated with such instructions 624. Non-limiting machine-readable medium examples may include solid-state memories and optical and magnetic media. In an example, a massed machine-readable medium comprises a machine-readable medium 622 with a plurality of particles having invariant (e.g., rest) mass. Accordingly, massed machine-readable media are not transitory propagating signals. Specific examples of massed machine-readable media may include non-volatile memory, such as semiconductor memory devices (e.g., electrically programmable read-only memory (EPROM), electrically erasable programmable read-only memory (EEPROM)), and flash memory devices; magnetic disks, such as internal hard disks and removable disks: magneto-optical disks; and CD-ROM and DVD-ROM disks. The instructions 624 may further be transmitted or received over a communications network 626 using a transmission medium via the network interface device 620.

Although an embodiment has been described with reference to specific example embodiments, it will be evident that various modifications and changes may be made to these embodiments without departing from the broader scope of the inventive subject matter. Accordingly, the specification and drawings are to be regarded in an illustrative rather than a restrictive sense. The accompanying drawings that form a part hereof, show by way of illustration, and not of limitation, specific embodiments in which the subject matter may be practiced. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This Detailed Description, therefore, is not to be taken in a limiting sense, and the scope of various embodiments is defined only by the appended claims, along with the full range of equivalents to which such claims are entitled.

Such embodiments of the inventive subject matter may be referred to herein, individually and/or collectively, by the term “invention” merely for convenience and without intending to voluntarily limit the scope of this application to any single invention or inventive concept if more than one is disclosed. Thus, although specific embodiments have been illustrated and described herein, it should be appreciated that any arrangement calculated to achieve the same purpose may be substituted for the specific embodiments shown. This disclosure is intended to cover all adaptations or variations of various embodiments. Combinations of the above embodiments, and other embodiments not specifically described herein, will be apparent to those of skill in the art upon reviewing the above description.

1. A valve flexure for a flow control valve, the valve flexure comprising:
a first diaphragm;
a second diaphragm, the second diaphragm directly or indirectly connected to the first diaphragm about a peripheral portion of the valve flexure, the connected first and second diaphragms enclosing an inner volume of the valve flexure; and
a heat transfer medium disposed within the inner volume of the valve flexure.

2. The valve flexure of claim 1, wherein a configuration of the first and second diaphragms and the heat transfer medium is selected to provide a specified dynamic response for the valve flexure or the valve.

3. The valve flexure of claim 1, wherein a configuration of the first and second diaphragms and the heat transfer medium is selected to provide a specified heat transfer characteristic of the valve flexure.

4. The valve flexure of claim 1, wherein a valve opening or valve closing movement of the first diaphragm induces a simultaneous or corresponding valve opening or valve closing movement of the second diaphragm.

5. The valve flexure of claim 1, wherein the heat transfer medium is incompressible.

6. The valve flexure of claim 1, wherein the valve flexure is devoid of a side wall.

7. The valve flexure of claim 1, wherein the first diaphragm is connected to the second diaphragm by a side wall.

8. The valve flexure of claim 7, wherein the side wall defines a cylindrical side wall extending around a circumference of the valve flexure.

9. The valve flexure of claim 7, wherein the side wall includes a bellows.

10. The valve flexure of claim 1, wherein the valve flexure includes an asymmetry with respect to the first and second diaphragms.

11. The valve flexure of claim 10, wherein a degree of the asymmetry is selected to provide a specified dynamic response of the flexure.

12. The valve flexure of claim 1, wherein the first diaphragm or the second diaphragm includes one or more of the following materials: SPRN 510, SPRN 100, and ELGILOY.

13. The valve flexure of claim 1, wherein the heat transfer medium has a dynamic viscosity of 1e-4 to 2e-2 Pa-s.

14. The valve flexure of claim 1, wherein the heat transfer medium has a thermal conductivity of 0.1 to 0.7 W/m° K.

15. The valve flexure of claim 1, wherein the heat transfer medium includes an alcohol.

16. The valve flexure of claim 1, wherein the heat transfer medium includes a dual-phase medium.

17. The valve flexure of claim 16, wherein the dual-phase medium moves or cycles between compressible and incompressible forms based on a valve flow control characteristic, valve status, or an operating condition.

18. A flow control valve comprising h valve flexure of claim 1.

19. A flow control valve comprising:
an inlet to admit a gas or vapor into the valve;
an outlet to discharge the gas or vapor from the valve;
a valve flexure to open or close the valve, the valve flexure movable to seat on and unseat from a valve seal located between the inlet and outlet of the valve;
a periphery of the valve flexure connected to one or more valve components, the connection defining or partitioning out an atmospheric side of the flow control valve; and
an interstitial liquid located above the valve flexure, the interstitial liquid occupying, on the atmospheric side of the valve, at least some interstitial spaces adjacent or between the one or more valve components of the valve.

20. The flow control valve of claim 19, further comprising an interstitial fluid column or reservoir.

21. The flow control valve of claim 19, wherein the interstitial liquid is filled to a depth in a range of 1-30 mm above the valve flexure, or within the valve.

22. The flow control valve of claim 19, wherein the interstitial liquid has a dynamic viscosity of 1e-4 to 2e-2 Pa-s.

23. The flow control valve of claim 19, wherein the interstitial liquid has a thermal conductivity of 0.1 to 0.7 W/m° K.

24. The flow control valve of claim 19, wherein the interstitial liquid includes an alcohol.

25. The flow control valve of claim 19, wherein the interstitial liquid includes a dual-phase medium.

26. A substrate processing system comprising;
a processing chamber;
a gas or vapor distribution device; and
a flow control valve connected to the gas or vapor distribution device, the flow control valve including the valve flexure of claim 1.

27. The substrate processing system of claim 26, wherein the flow control valve comprises the flow control valve of claim 19.

28. A substrate processing system comprising;
a processing chamber;
a gas or vapor distribution device; and
a flow control valve connected to the gas or vapor distribution device, the flow control valve including the flow control valve of claim 19.

29. A method of implementing a substrate processing system, the method including:
installing a flow control valve in the processing system, the flow control valve including:
an inlet to admit a gas or vapor into the flow control valve;
an outlet to discharge the gas or vapor from the flow control valve;
a valve flexure to open or close the flow control valve, the valve flexure movable to seat on and unseat from a valve seal located between the inlet and outlet of the flow control valve; and
a periphery of the valve flexure connected to one or more valve components, the connection defining or partitioning out an atmospheric side of the flow control valve;
the method further comprising:
providing an interstitial liquid located above the valve flexure, the interstitial liquid occupying, on the atmospheric side of the valve, at least some interstitial spaces adjacent or between the one or more valve components of the valve.

30. The method of claim 29, further comprising providing the valve flexure for the flow control valve, the valve flexure comprising:
a first diaphragm;
a second diaphragm, the second diaphragm directly or indirectly connected to the first diaphragm about a peripheral portion of the valve flexure, the connected first and second diaphragms enclosing an inner volume of the valve flexure; and
a heat transfer medium disposed within the inner volume of the valve flexure.

31. The method of claim 29, further comprising passing a gas or vapor through the flow control valve.

32. (canceled)
